(19) United States
(12) Patent Application Publication
(10) Pub. No.: US 2016/0041469 A1
(43) Pub. Date: Feb. 11, 2016

(54) METHOD FOR PATTERNING PHOTOSENSITIVE RESIN LAYER

(71) Applicant: CANON KABUSHIKI KAISHA, Tokyo (JP)

(72) Inventors: Ken Ikegame, Ebina-shi (JP); Miho Ishii, Kawasaki-shi (JP)

(21) Appl. No.: 14/817,022

(22) Filed: Aug. 3, 2015

(30) Foreign Application Priority Data
Aug. 7, 2014 (JP) 2014-161635

(51) Int. Cl. G03F 7/20

(52) U.S. Cl. CPC G03F 7/2035

(57) ABSTRACT

A method for patterning a photosensitive resin layer includes a forming process of forming, on a first photosensitive resin layer containing a first resin, a second photosensitive resin layer containing a second resin different from the first resin and a solvent and a patterning process of patterning the first photosensitive resin layer and the second photosensitive resin layer by simultaneously exposing and developing the first photosensitive resin layer and the second photosensitive resin layer, in which the second photosensitive resin layer is a water-repellent layer and the second resin has higher solubility in the solvent than the solubility of the first resin.

### BACKGROUND OF THE INVENTION

1. Field of the Invention

The present invention relates to a method for patterning a photosensitive resin layer.

2. Description of the Related Art

By patterning a photosensitive resin layer by photolithography, a structure can be formed with high accuracy. In the photolithography, the photosensitive resin layer is subjected to pattern exposure, heated, and then developed. In such patterning of the photosensitive resin layer, two or more of the photosensitive resin layers are formed, and then simultaneously patterned in some cases. Japanese Patent Laid-Open No. 2014-81440 describes forming a water-repellent layer as an upper layer on a layer of a channel forming member which is a lower layer, forming the two layers, and then simultaneously patterning the layers.

### SUMMARY OF THE INVENTION

The present invention is a method for patterning a photosensitive resin layer, and the method includes a forming process of forming, on a first photosensitive resin layer containing a first resin, a second photosensitive resin layer containing a second resin different from the first resin and a solvent and a patterning process of patterning the first photosensitive resin layer and the second photosensitive resin layer by simultaneously exposing and developing the first photosensitive resin layer and the second photosensitive resin layer, in which the second photosensitive resin layer is a water-repellent layer and the second resin has higher solubility in the solvent than the solubility of the first resin.

Further features of the present invention will become apparent from the following description of exemplary embodiments with reference to the attached drawings.

### BRIEF DESCRIPTION OF THE DRAWINGS

FIGS. 1A to 1G are views illustrating a method for producing a liquid ejection head.

FIGS. 2A to 2D are views illustrating formed photosensitive resin layers.

### DESCRIPTION OF THE EMBODIMENTS

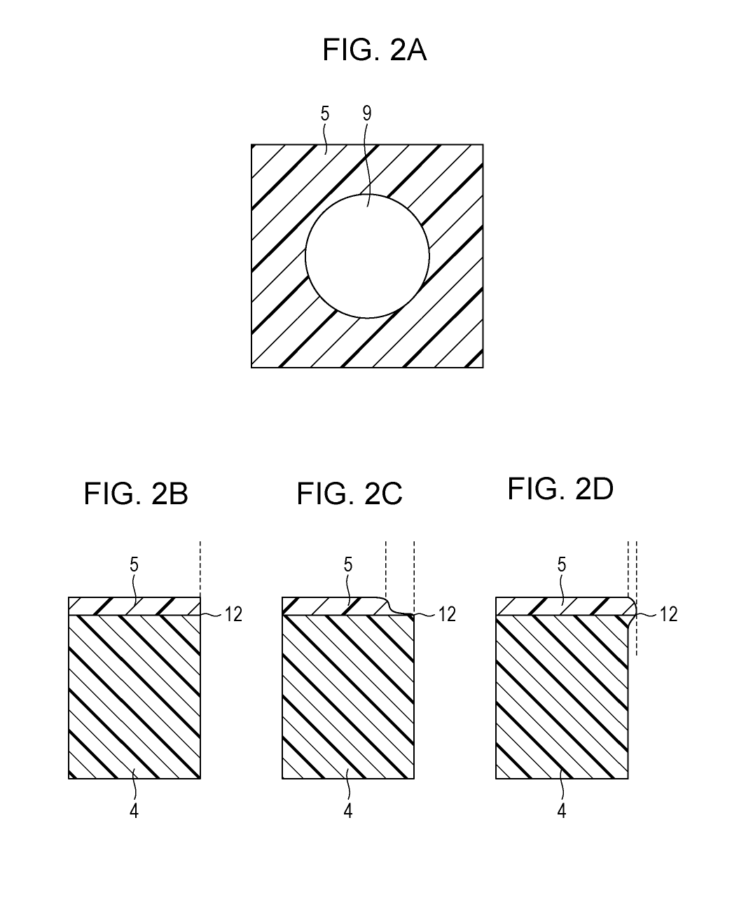

According to an examination of the present inventors, when simultaneously patterning formed photosensitive resin layers described in Japanese Patent Laid-Open No. 2014-81440 by photolithography, desired patterning has not been able to be performed in some cases. For example, a level difference has been formed at the boundary of the lower layer and the upper layer as illustrated in FIG. 2C or a projection has been formed at the boundary of the lower layer and the upper layer as illustrated in FIG. 2D in some cases.

Accordingly, even in the case where photosensitive resin layers are formed, and then simultaneously patterned by photolithography, the present invention achieves good patterning.

The present invention relates to a patterning method including forming a second photosensitive resin layer which is an upper layer on a first photosensitive resin layer which is a lower layer, and then simultaneously exposing and developing the layers to perform patterning of the layers by photolithography.

The first photosensitive resin layer contains a first resin. The first resin is suitably a photopolymerizable resin having a polyfunctional cationic photopolymerizable group. Moreover, the first photosensitive resin layer is suitably a resin which is a solid at normal temperature (25° C.). Examples of such a resin include epoxy resin having an epoxy group, for example. Examples of the epoxy resin include a bisphenol A type epoxy resin, a bisphenol E type epoxy resin, and a novolac type epoxy resin, for example. Examples of commercially available epoxy resin include “CELLOXIDE 2021”, “GT-300 series”, “GT-400 series”, and “EHPE-3150” (Trade name) manufactured by Daicel Corporation, “157S70” (Trade name) manufactured by Mitsubishi Chemical Corporation, “EPICLON N-695” and “EPICLON N-865” (Trade name) manufactured by Dainippon Ink & Chemicals, “SU8” (Trade name) manufactured by Nippon Kayaku Co., Ltd., “VG3101” (Trade name) and “EPOX-MKR1710 (Trade name) manufactured by Printec Co., “DENACOL series” manufactured by Nagase ChemteX Corporation, and the like. The first resin may be used alone or in combination of two or more kinds thereof. When the first resin is the epoxy resin, the epoxy equivalent is preferably 2000 or less and more preferably 1000 or less. Due to the fact that the epoxy equivalent is 2000 or less, a sufficient crosslink density is obtained in a curing reaction, the glass transition temperature of a cured product is difficult to decrease, and high adhesiveness is obtained. The epoxy equivalent of the first resin is suitably 50 or more. The epoxy equivalent is measured by JISK-7236. As the first resin, “SU-8 series” and “KMPR-1000” (Trade name) manufactured by Nippon Kayaku Co., Ltd., “TMMR S2000” and “TMMFS 2000” (Trade name) manufactured by TOKYO OHKA KOGYO, and the like commercially available as a negative resist can also be used.

The first photosensitive resin layer may contain a solvent or may be in the form of a film in a dry state. At least either the first photosensitive resin layer or the second photosensitive resin layer suitably contains a photoacid generating agent. As the photoacid generating agent contained in the first photosensitive resin layer, a general photoacid generating agent may be used. For example, those mentioned as the photoacid generating agent contained in the second photosensitive resin layer mentioned later can be used.

Next, the second photosensitive resin layer is described. The second photosensitive resin layer contains a second resin and a solvent.

The second resin is suitably a photopolymerizable resin having a polyfunctional cationic photopolymerizable group, and the same resin examples as the resin examples mentioned as the first resin are suitably used. However, resin different from the first resin, i.e., resin having a different structure, is used.

The second photosensitive resin layer is formed on the first photosensitive resin layer for use. For example, when producing a liquid ejection head by forming photosensitive resin layers, and then patterning the layers, the second photosensitive resin layer can be a water-repellent layer which imparts water repellency to the surface of the liquid ejection head. In this case, the first photosensitive resin layer is provided on a substrate, and then the second photosensitive resin layer is formed thereon, whereby the second photosensitive resin layer is the outermost surface. When using the second photosensitive resin layer as the water-repellent layer, it is suitable for the second photosensitive resin layer to contain, in addition to the second resin and the solvent, a condensate obtained by condensing a hydrolytic silane compound having a perfluoropolyether group and a hydrolytic silane compound having an epoxy group. Hereinafter, a case where the second photosensitive resin layer is the water-repellent layer is described as an example.

First, the condensate is described. The condensate is a condensate obtained by condensing a hydrolytic silane compound having a perfluoropolyether group and a hydrolytic silane compound having an epoxy group.

The perfluoropolyether group is a group in which one or more units containing a perfluoroalkyl groups and an oxygen atom are connected to each other. Specifically, the perfluoropolyether group (indicated as Rₚ) is suitably a group represented by the following formula (5). In Formula (5), each part represented in the brackets is each unit and the number represented by o, p, q, or r which represents the number of each unit is referred to as the repetition unit number herein.

### Formula (5)

In Formula (5), o, p, q, and r each represent an integer of 0 or 1 or more and at least one of o, p, q, and r is an integer of 1 or more. o, p, q, or r is suitably an integer of 1 to 30.

The hydrolytic silane compound having a perfluoropolyether group is not particularly limited and is suitably at least one of the compounds represented by the following formulae (1), (2), (3), and (4).

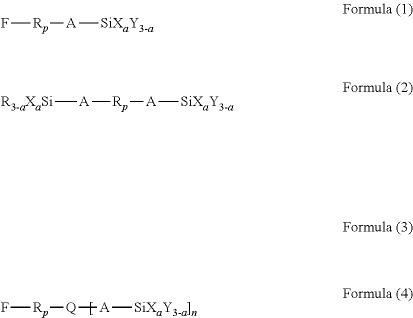

In Formulae (1), (2), (3), and (4), Rₚ represents a perfluoropolyether group represented by Formula (5) and A represents a bonding group having 1 to 12 carbon atoms. X represents a hydrolytic substituent, Y and R represent non-hydrolytic substituents, Z represents a hydrogen atom or an alkyl group, and Q represents a divalent or tervalent bonding group. Herein, Q is divalent, n and m=1 is established and when Q is tervalent, m=2 is established. a is an integer of 1 to 3 and m is an integer of 1 to 4.

Examples of Xs in Formulae (1), (2), (3), and (4) include a halogen atom, an alkoxy group, an amino group, a hydrogen atom, and the like, for example. Among the above, alkoxy groups, such as a methoxy group, an ethoxy group, and a propoxy group, are suitable from the viewpoint that a group desorbed by a hydrolysis reaction does not inhibit a cationic polymerization reaction and the reactivity is easily controlled. As the non-hydrolytic substituents Y and R, an alkyl group, a phenyl group, and the like having 1 to 20 carbon atoms are mentioned and the non-hydrolytic substituents Y and R may be the same functional group or different functional groups. As the alkyl group represented by Z, a methyl group, an ethyl group, a propyl group, and the like are mentioned. As Q, a carbon atom, a nitrogen atom, and the like are mentioned. Examples of the organic group having 1 to 12 carbon atoms represented by A include alkyl groups, such as a methyl group, an ethyl group, and a propyl group, and the like. Moreover, an alkyl group having a substituent may be used.

In Formulae (1), (2), (3), and (4), the repetition unit number in Rₚ is suitably an integer of 1 to 30. Depending on the structure of the perfluoropolyether group, the repetition unit number is more suitably an integer of 3 to 20.

The average molecular weight of Rₚ which represents a perfluoropolyether group in each of Formulae (1), (2), (3), and (4) is preferably 500 or more and 5000 or less and more preferably 500 to 2000. Due to the fact that the average molecular weight of Rₚ is 500 or more, sufficient water repellence is obtained. When the average molecular weight of Rₚ is 5000 or less, sufficient solubility in a solvent is obtained. The perfluoropolyether group is a mixture containing substances different in the repetition unit number (o, p, q, and r in Formula (1) and the like) in terms of characteristics in many cases. The average molecular weight of the perfluoropolyether group represents the average of the total molecular weight of the parts represented by the repetition units of Formula (5).

Suitable examples of the silane compound having a perfluoropolyether group include compounds represented by the following formulae (9), (10), (11), (12), and (13).

### Formula (9)

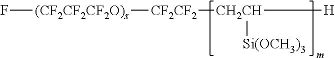

(In Formula (9), s represents an integer of 1 to 30 and m is an integer of 1 to 4.)

F—(CF₂CF₂CF₂O)ₜ—CF₂CF₂—CH₂O(CH₂)₃—Si(OCH₃)₃ Formula (10)

(In Formula (10), t represents an integer of 1 to 30.)

### Formula (11)

(In Formula (11), e and f represent integers of 1 to 30.)

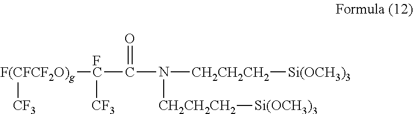

(In Formula (12), g represents an integer of 1 to 30.)

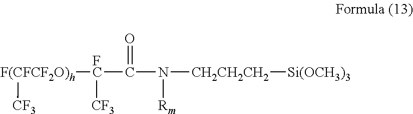

(In Formula (13), (Rₘ represents a methyl group or a hydrogen atom and h represents an integer of 1 to 30.)

In Formula (9) to Formula (13), s, t, e, f, g, and h each represent the repetition unit number and are suitably 3 to 20. When the values are smaller than 3, there is a tendency for the water repellency to decrease. When the values are larger than 20, the solubility in a solvent decreases. In particular, when performing a condensation reaction in a non-fluorine solvent, such as alcohol, the values are suitably 3 to 10.

Examples of commercially available perfluoropolyether groups containing silane compounds include “Optool DSX” and “Optool AES” manufactured by Daikin Industries, “KY-108” and “KY-164” manufactured by Shin-Etsu Chemical, “Novec1720” manufactured by Sumitomo 3M, “fluorolink S10” manufactured by Solvey Solexis, and the like.

The hydrolytic silane compound having an epoxy group is suitably a compound represented by the following formula (6).

R_{c}—SiX_{b}R_{(3-b)} Formula (6)

In Formula (6), R_{c} represents a non-hydrolytic substituent having an epoxy group, R represents a non-hydrolytic substituent, and X represents a hydrolytic substituent. b is an integer of 1 to 3. b is preferably 2 or 3 and more preferably 3.

In Formula (6), as R_{c}, a glycidoxypropyl group, an epoxycyclohexylethyl group, and the like are mentioned. As R, an alkyl group having 1 to 20 carbon atoms, a phenyl group, and the like are mentioned. As X, a halogen atom, an alkoxy group, an amino group, a hydrogen atom, and the like are mentioned. Among the above, alkoxy groups, such as a methoxy group, an ethoxy group, and a propoxy group, are suitable from the viewpoint that a group desorbed by a hydrolysis reaction does not inhibit a cationic polymerization reaction and the reactivity is easily controlled. Moreover, those which partially forms a hydroxyl group by hydrolysis or forms a siloxane bond by drying condensation may be used.

Among the hydrolytic silane compounds having an epoxy group represented by Formula (6), examples of the hydrolytic silane compounds in which X is an alkoxy group include glycidoxypropyltrimethoxysilane, glycidoxypropyltriethoxysilane, epoxycyclohexylethyltrimethoxysilane, epoxycyclohexylethyltriethoxysilane, glycidoxypropylmethyldimethoxysilane, glycidoxypropylmethyldiethoxysilane, glycidoxypropyldimethylmethoxysilane, glycidoxypropyldimethylethoxysilane, and the like.

The hydrolytic silane compounds having an epoxy group may be used alone or in combination of two or more kinds thereof.

The content of the hydrolytic silane compound having an epoxy group is preferably 20% by mol or more and 80% by mol or less and more preferably 30% by mol or more and 70% by mol or less when calculated under the conditions where the total amount of the number of moles of the hydrolytic silane compound to be used is 100% by mol from the viewpoint of obtaining adhesiveness with the first photosensitive resin layer and durability as a water-repellent layer. When the content is 20% by mol or more, the durability of a coating film becomes high. When the content is 80% by mol or less, a reduction in water-repellency can be suppressed due to the polarity of the epoxy group.

A condensate obtained by condensing the hydrolytic silane compound having a perfluoropolyether group and a hydrolytic silane compound having an epoxy group is suitably a condensate obtained by further condensing a hydrolytic silane compound having an alkyl group or an aryl group. The hydrolytic silane compound having an alkyl group or an aryl group is a compound represented by the following formula (14).

(R_{d})ₐ—SiX₍₄₋ₐ₎ Formula (14)

In Formula (14), R_{d} is an alkyl group or an aryl group and X is a hydrolytic substituent. a is an integer of 1 to 3. As R_{d}, a methyl group, an ethyl group, a propyl group, a butyl group, a hexyl group, a phenyl group, a naphthyl group, and the like are mentioned. Specific examples of the hydrolytic silane compound represented by Formula (14) include methyl trimethoxy silane, methyl triethoxy silane, methyl tripropoxy silane, ethyl trimethoxy silane, ethyl triethoxy silane, ethyl tripropoxy silane, propyl trimethoxy silane, propyl triethoxy silane, propyl tripropoxy silane, dimethyl dimethoxy silane, dimethyl diethoxy silane, phenyl trimethoxy silane, phenyl triethoxy silane, trimethyl methoxy silane, trimethyl ethoxy silane, and the like. These hydrolytic silane compounds represented by Formula (14) may be used alone or in combination of two or more kinds thereof.

By blending the hydrolytic silane compound represented by Formula (14), the polarity and the crosslink density of the condensate can be controlled. When a non-cationic polymerizable silane compound, such as the hydrolytic silane compound represented by Formula (14), is used in combination, the degree of freedom of substituents, such as a perfluoropolyether group and an epoxy group, increases. Therefore, the orientation to the side of the interface with the air of the perfluoropolyether group, the polymerization of the epoxy group, the condensation of an unreacted silanol group, and the like are accelerated. The presence of a nonpolar group, such as an alkyl group, is suitable in the respects that cleavage of a siloxane bond is suppressed and water repellency and durability increase.

When adding the hydrolytic silane compound represented by Formula (14), the content is preferably 5% by mol or more and 70% by mol or less and more preferably 10% by mol or more and 50% by mol or less.

The content of each hydrolytic silane compound to be used for the production of the condensate is determined as appropriate according to the usage form thereof. The content of the hydrolytic silane compound having a perfluoropolyether group is suitably 0.01% by mol or more and 5% by mol less when calculated under the conditions where the total amount of the number of moles of the hydrolytic silane compound to be used is 100% by mol. The content is more suitably 0.1% by mol or more. The content is more suitably 4% by mol or less. When the content is 0.01% by mol or more, the water repellency becomes good. When the content is 5% by mol or less, aggregation and precipitation of the hydrolytic silane compounds having a perfluoropolyether group can be suppressed, so that a uniform solution is easily obtained.

Each hydrolytic silane compound is condensed to be used as a condensate. A condensation reaction is performed by advancing hydrolysis and a condensation reaction by heating the hydrolytic silane compound in a solvent in the presence of water. A desired condensate can be obtained by controlling the hydrolysis/condensation reaction as appropriate by temperature, time, concentration, pH, and the like. The condensate is synthesized in a polar solvent having oxygen atoms of a hydroxyl group, a carbonyl group, an ether bond, and the like. Specific examples include non-fluorine polar solvents, such as alcohols, such as methanol, ethanol, propanol, isopropanol, and butanol, ketones, such as methyl ethyl ketone and methyl isobutyl ketone, esters, such as ethyl acetate and butyl acetate, ethers, such as diglyme and tetrahydrofuran, and glycols, such as diethylene glycol. Since water is used for the synthesis, alcohols having high solubility in water are the most suitable. It is suitable to perform the heating at 100° C. or less from the viewpoint of the moisture amount control. Therefore, when performing the reaction by heating and refluxing, polar solvents having a boiling point of 50° C. or higher and 100° C. or less are suitable. These polar solvents may be used alone or in combination of two or more kinds thereof.

The addition amount of water to be used for the reaction is preferably 0.5 Eq or more and 3 Eq or less and more preferably 0.8 Eq or more and 2 Eq or less to a hydrolytic substituent of the hydrolytic silane compound. Due to the fact that the addition amount of water is 0.5 Eq or more, a sufficient reaction rate in the hydrolysis/condensation reaction is obtained. Due to the fact that the addition amount of water is 3 Eq or less, the precipitation of the hydrolytic silane compound having a perfluoropolyether group can be suppressed.

The second photosensitive resin layer suitably contains a photoacid generating agent. The photoacid generating agent cures the epoxy group and the silanol group in the coating film by light irradiation. Due to the fact that the photoacid generating agent is contained, the curing of the second resin can be accelerated. When the second photosensitive resin layer does not contain a photoacid generating agent and the first photosensitive resin layer contains a photoacid generating agent, the curing of the second photosensitive resin layer proceeds by the photoacid generating agent to be supplied from the first photosensitive resin layer. However, the supply amount of the photoacid generating agent becomes small, and thus sufficient water repellent performance is not obtained in some cases. Therefore, the second photosensitive resin layer suitably contains the photoacid generating agent. The “contain” used herein means that a coating liquid and the like forming the second photosensitive resin layer contain the photoacid generating agent before the second photosensitive resin layer is formed on the first photosensitive resin layer by coating or the like.

The photoacid generating agent suitably has a cationic part structure represented by Formula (7) and an anionic part structure represented by Formula (8) in one to one relationship.

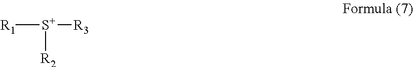

### Formula (8)

Specific examples of Formula (7) and Formula (8) are shown below. The cationic part structure represented by Formula (7) has a feature in having i-ray sensitivity which allows an increase in the wavelength of the absorption wavelength of the photoacid generating agent, which has been difficult to achieve, due to having two or more oxygen atoms. On the other hand, the anionic part structure represented by Formula (8) has a feature in that, after exposed to i-rays, the Formula (7) component is decomposed, and then acid originating from the structure of Formula (8) is generated, and thus a cationic polymerization reaction of the epoxy group can be started and accelerated by the action of the generated acid. The generated acid more suitably has acid strength which allows sufficient curing of an epoxy polymerizable compound. The acid strength which allows sufficient curing of the epoxy polymerizable compound means strong acid equal to or higher than the strength of hexafluoroantimonic acid among Lewis acids, i.e., Hammett acidity function—HO=18 or more. The acid strength means strength equal to or higher than the strength of nonafluorobutanesulfonic acid among Broensted acids, i.e., PKa=−3.57 or more. An example (left side) of Formula (7) and an example (right side) of Formula (8) are represented by Formula (15).

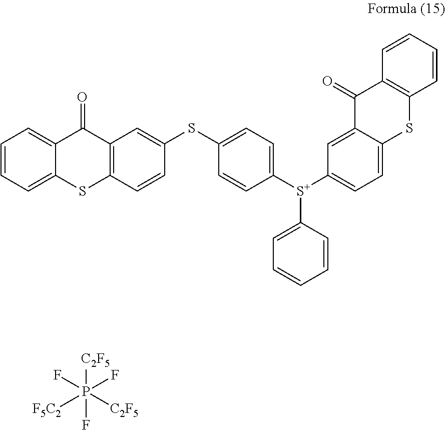

In the composition, R₁ to R₃ each in the cationic part structure represented by Formula (7) represent an organic group having 1 to 30 carbon atoms which may have a substituent. However, at least two or more oxygen atoms are contained in all the constituent atoms of R₁ to R₃. In Formula (8), D is selected from a carbon atom, a nitrogen atom, a phosphorus atom, a boron atom, and an antimony atom and E is selected from —S(═O)₂—, a fluoride alkyl group, —CF₂—O—, —CF₂—C(═O)—, —CF₂—C(═O)—O—, —CF₂—O—C(═O)—, and a single bond. R₄ represents a hydrocarbon group having 1 to 30 carbon atoms which may be replaced with a fluorine atom. m and n represent integers of m+n=3 and n=0 to 2 when D is a carbon atom or integers of m+n=2 and n=0 or 1 when D is a nitrogen atom. m and n represent integers of m+n=6 and n=0 to 6 when D is a phosphorus atom or an antimony atom or integers of m+n=4 and n=0 to 3 when D is a boron atom.

Suitable specific examples of the cationic part structure represented by Formula (7) are represented by Formula (16)-(19).

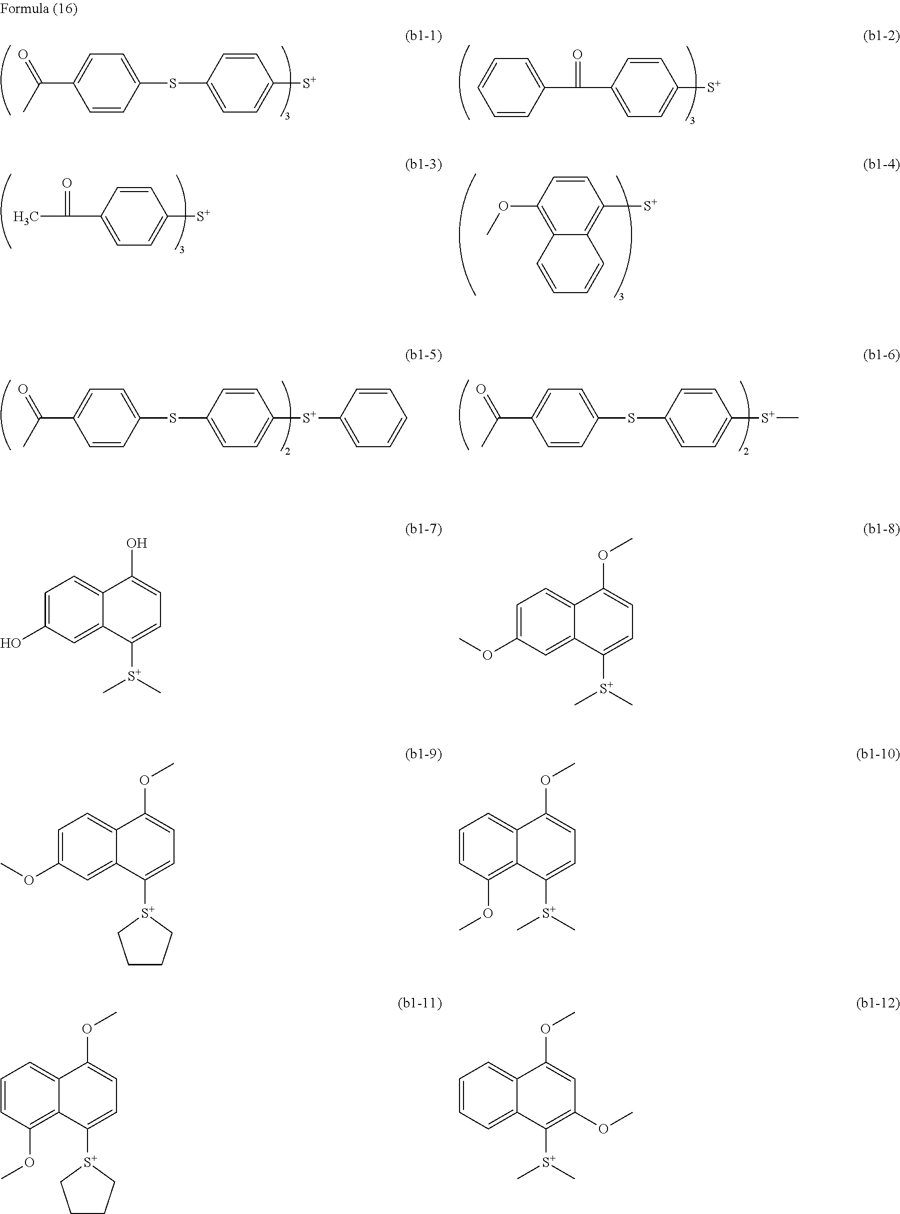

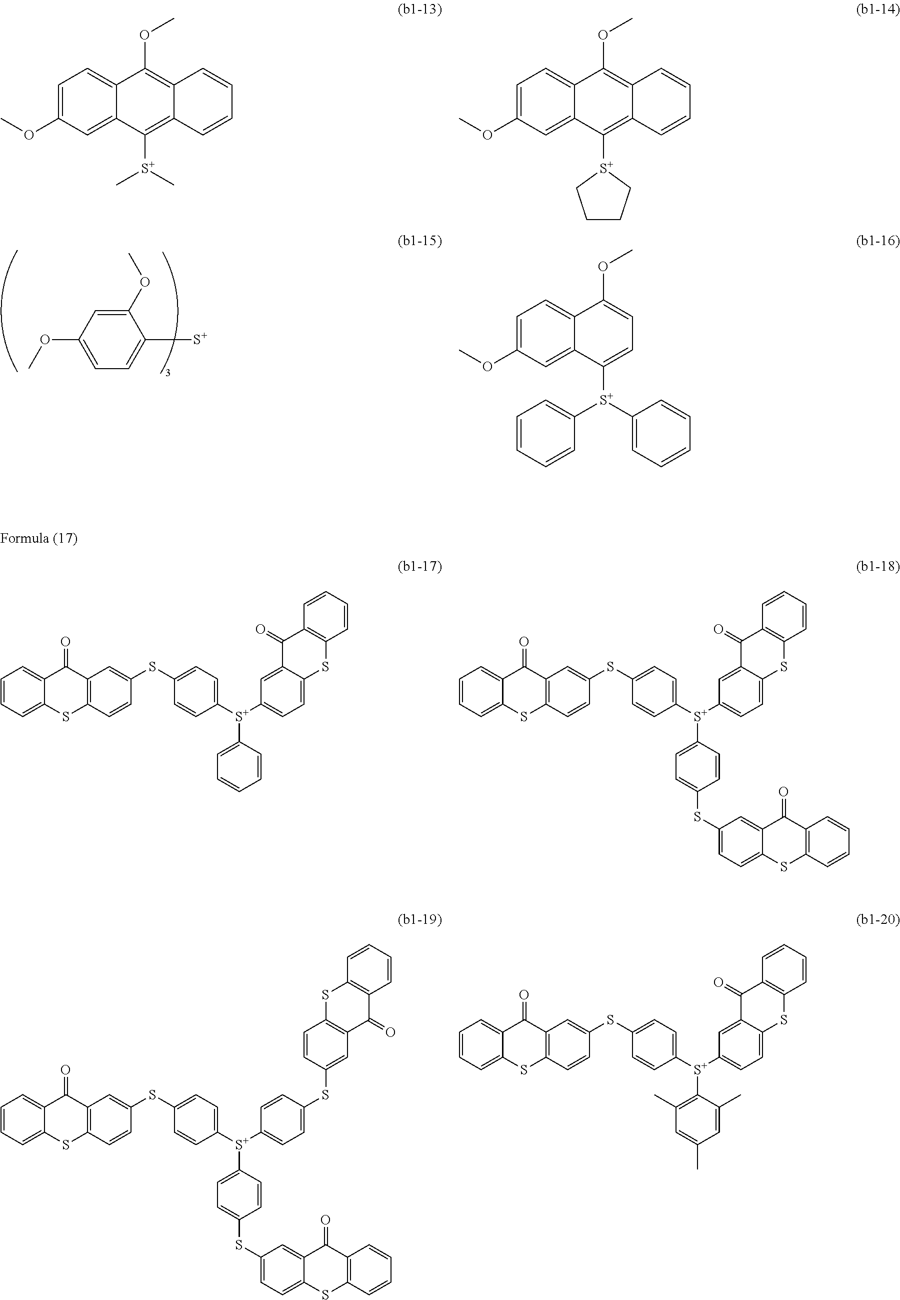

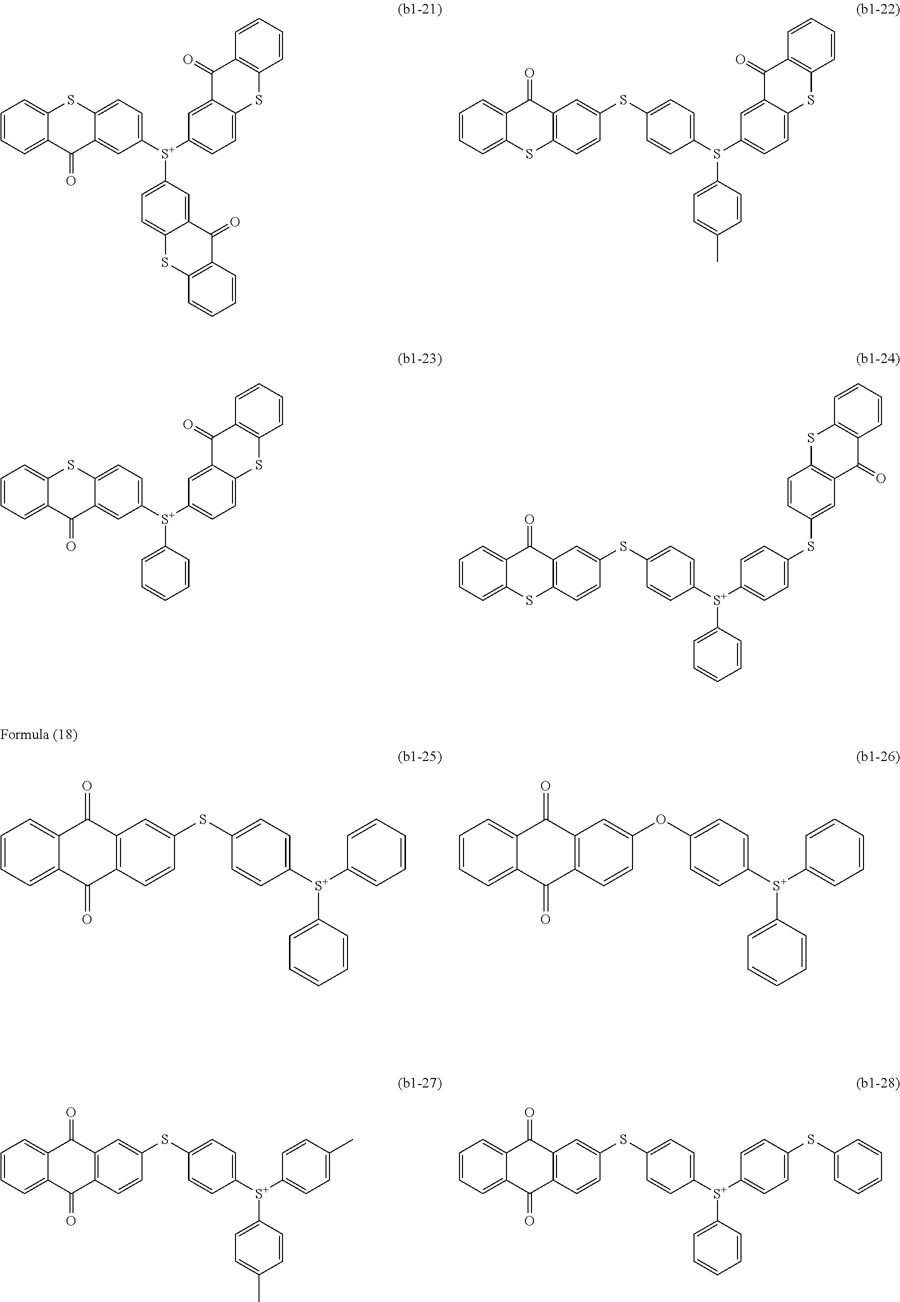

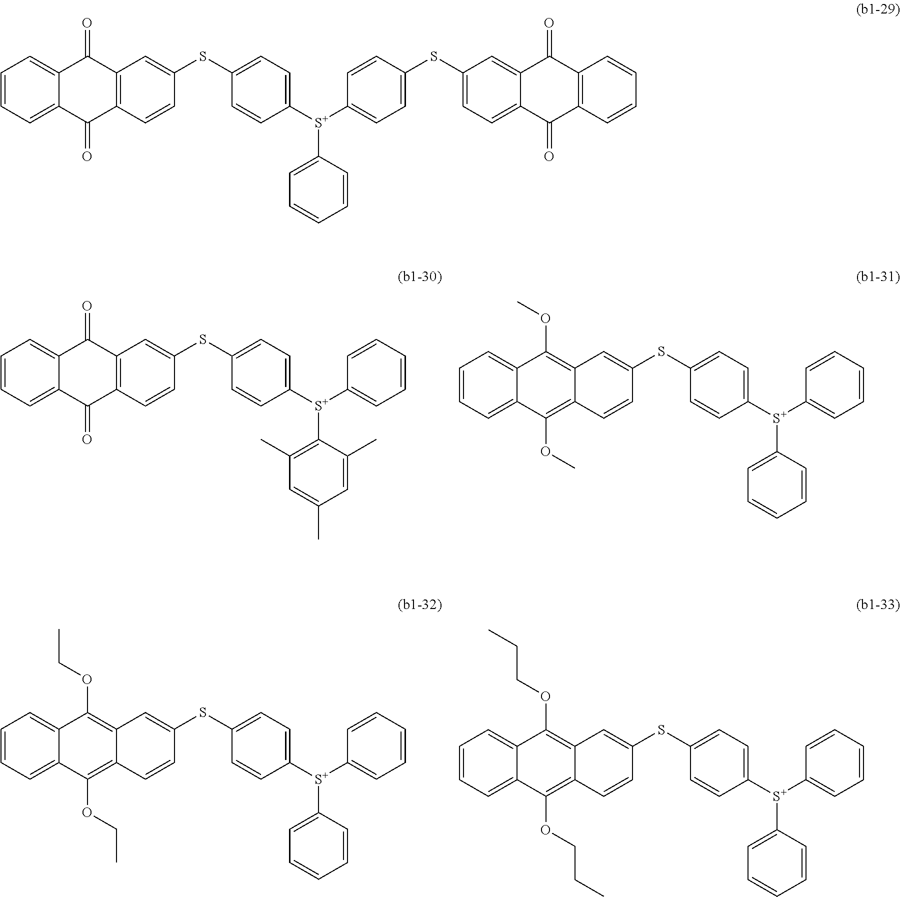 [SMILES: O=C1c2ccccc2C(=O)c2cc(Sc3ccc([S+](c4ccccc4)c4ccc(Sc5ccc6c(c5)C(=O)c5ccccc5C6=O)cc4)cc3)ccc21 ; Cc1cc(C)c([S+](c2ccccc2)c2ccc(Sc3ccc4c(c3)C(=O)c3ccccc3C4=O)cc2)c(C)c1 ; COc1c2ccccc2c(OC)c2cc(Sc3ccc([S+](c4ccccc4)c4ccccc4)cc3)ccc12 ; CCOc1c2ccccc2c(OCC)c2cc(Sc3ccc([S+](c4ccccc4)c4ccccc4)cc3)ccc12 ; CCCOc1c2ccccc2c(OCCC)c2cc(Sc3ccc([S+](c4ccccc4)c4ccccc4)cc3)ccc12]

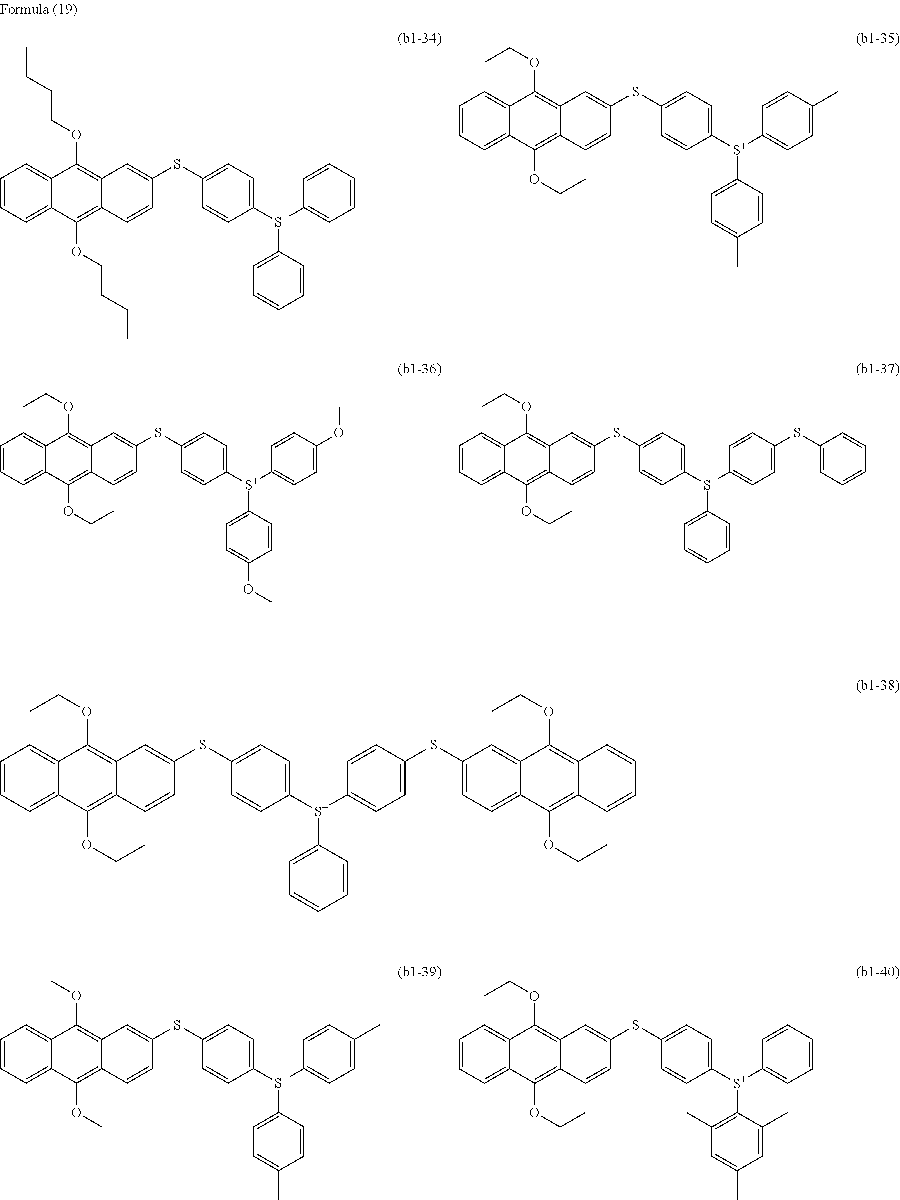

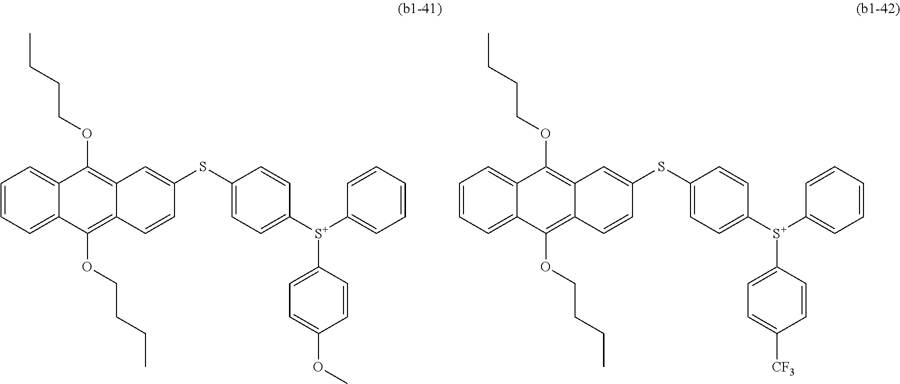 [SMILES: CCCCOc1c2ccccc2c(OCCCC)c2cc(Sc3ccc([S+](c4ccccc4)c4ccc(OC)cc4)cc3)ccc12 ; CCCCOc1c2ccccc2c(OCCCC)c2cc(Sc3ccc([S+](c4ccccc4)c4ccc(C(F)(F)F)cc4)cc3)ccc12]

In the cationic part structure represented by Formula (7), a structure in which at least one of the oxygen atoms contained in R₁ to R₃ is a cyclic carbonyl group is particularly suitable. Specific examples of the structure include (b1-17) to (b1-30) shown above.

In the composition of the present invention, in the anionic part structure represented by Formula (8), D is selected from a carbon atom, a nitrogen atom, a phosphorus atom, a boron atom, and an antimony atom. E is selected from —S(═O)₂—, a fluoride alkyl group, —CF₂—O—, —CF₂—C(═O)—, —CF₂—C(═O)—O—, —CF₂—O—C(═O)—, and a single bond. R₄ represents a hydrocarbon group having 1 to 30 carbon atoms which may be replaced with a fluorine atom. m and n represent integers of m+n=3 and n=0 to 2 when D is a carbon atom or integers of m+n=2 and n=0 or 1 when D is a nitrogen atom. m and n represent integers of m+n=6 and n=0 to 6 when D is a phosphorus atom or an antimony atom or an integers of m+n=4 and n=0 to 3 when D is a boron atom.

Suitable specific examples of the anionic part structure represented by Formula (8) are shown below.

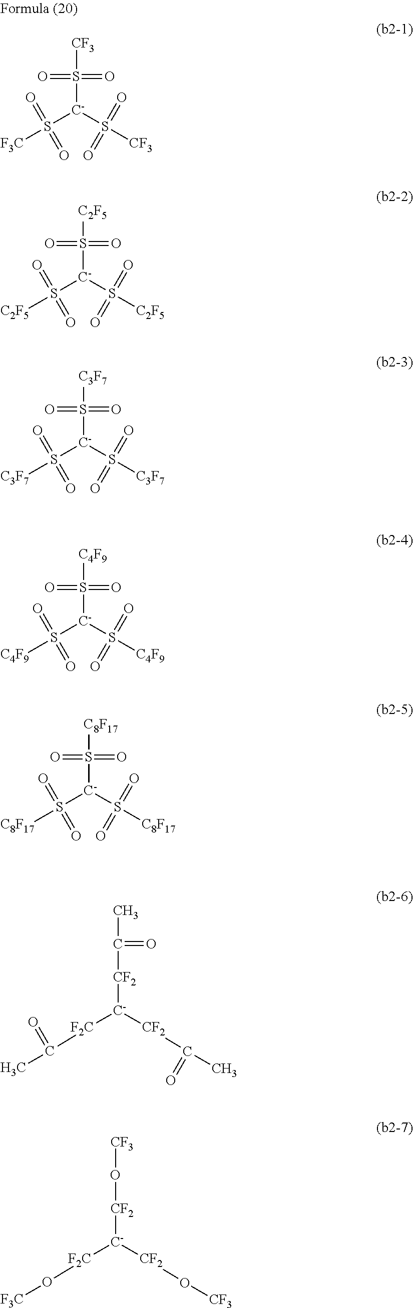

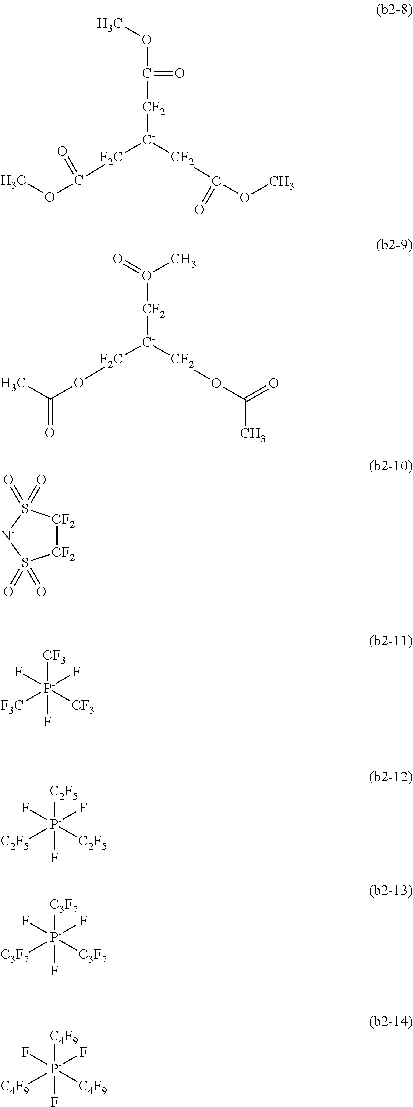

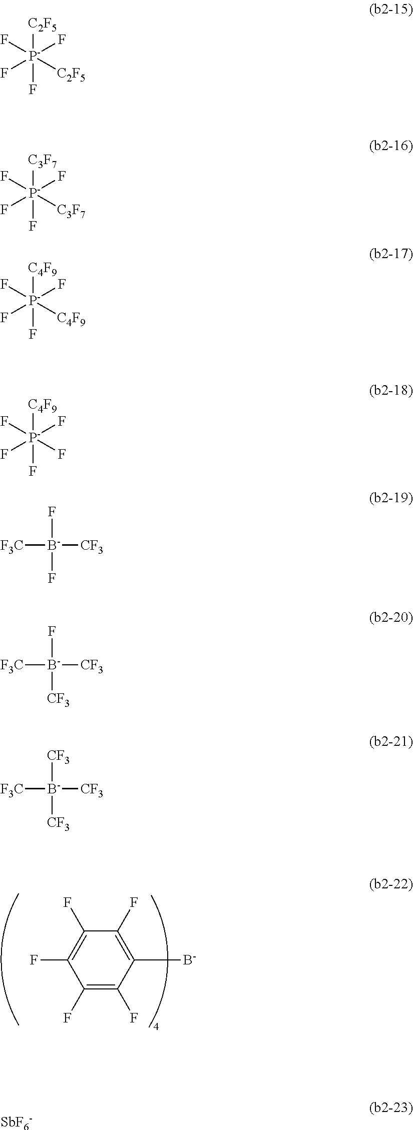

Among the anionic part structures represented by Formula (8), a structure in which D is a phosphorus atom is suitable, and the structures of (b2-11) to (b2-18) are suitable.

Examples of commercially available photoacid generating agents include “CPI-410S” (Trade name) manufactured by San-Apro Ltd., “SP-172” (Trade name) manufactured by ADEKA, and the like, for example. The photoacid generating agents can be used alone or in combination of two or more kinds thereof. The content of the photoacid generating agent in the second photosensitive resin layer is generally 0.01 part by mass or more and 20 parts by mass or less and more preferably 0.1 part by mass or more and 10 parts by mass or less based on the total solid content. By setting the content of the photoacid generating agent in the second photosensitive resin layer to 0.01 part by mass or more and 20 parts by mass or less, a level difference can be made hard to form between the first photosensitive resin layer and the second photosensitive resin layer.

The first photosensitive resin layer and the second photosensitive resin layer can be formed by, for example, applying a coating liquid by a coating device, such as a spin coater, a die coater, a slit coater, and a spray coater, for example. Moreover, the layers can also be formed by dip coating. When the second photosensitive resin layer is a water-repellent layer, the content of a condensate of a solution containing the condensate is preferably 0.1% by mass or more and 50% by mass or less and more preferably 1% by mass or more and 30% by mass or less. When the content of the condensate is 0.1% by mass or more and 50% by mass or less, good water repellency and durability are obtained and uniform water repellency is obtained on the entire surface of the second photosensitive resin layer.

The thickness of the second photosensitive resin layer is preferably 50 nm or more and 10000 nm or less and more preferably 80 nm or more and 5000 nm or less. When the film thickness is smaller than 50 nm, uniform water repellency is hard to obtain and the durability is insufficient in some cases. When the film thickness is larger than 10000 nm, water repellency is likely to develop not only on the surface but in the pattern cross section. The thickness of the first photosensitive resin layer is not particularly limited and is suitably 5000 nm or more.

After forming the first photosensitive resin layer and the second photosensitive resin layer, the layers are irradiated with light, and then cured by light or heat as necessary. By the use of the cationic polymerization of the epoxy group and condensation polymerization of silane (silanol group) by heat for the curing reaction, high durability can be developed even in the case of a thin film.

When the second resin of the second photosensitive resin layer is an epoxy resin and further the second photosensitive resin layer contains the photoacid generating agent, a fine pattern can be formed. In the case where patterning is performed by light, after passing through development treatment and the like, stronger light irradiation or heating is needed. Appropriate light irradiation or heating is performed to sufficiently cure an unreacted group, whereby a layer with high durability can be obtained.

The second photosensitive resin layer contains a solvent. When the second photosensitive resin layer contains a condensate, the solvent is suitably a solvent used when performing the condensation reaction of the condensate. The solvent dissolves the second resin and two or more kinds of solvents may be used.

Herein, the solvent contained in the second photosensitive resin layer is a solvent which is easier to dissolve the second resin of the second photosensitive resin layer than the first resin of the first photosensitive resin layer. In other words, the second resin has higher solubility in the solvent contained in the second photosensitive resin layer than the solubility of the first resin. By forming such a configuration, dissolution is hard to occur between the first photosensitive resin layer and the second photosensitive resin layer. Therefore, highly accurate patterning can be performed. When the second photosensitive resin layer is a water-repellent layer, the water-repellent layer can be formed up to the pattern end while controlling the compatibility with the first photosensitive resin layer of the condensate. Between the first resin and the second resin, when the solubility in the solvent contained in the second photosensitive resin layer is the same or when the solubility of the first resin is higher than that of the second resin, the shape near the boundary between the first photosensitive resin layer and the second photosensitive resin layer is broken or coating distribution unevenness occurs in some cases.

As one of the standards of the solubility, a solubility parameter (hereinafter referred to as an SP value) is mentioned. It is known that, when a difference in the SP value is within 0.5, the solubility is high, and also, when the SP value is larger, the dissolving power and the polarity are higher. Therefore, as the solvent contained in the second photosensitive resin layer, a solvent having an SP value closer to the SP value of the second resin than the SP value of the first resin is used. The SP value of the solvent can be calculated from generally known Small formula and the like. The SP value of resin can be calculated from the Fedors formula and the like.

Hereinafter, a method for patterning a photosensitive resin layer by photolithography is described with reference to an example of producing a liquid ejection head.

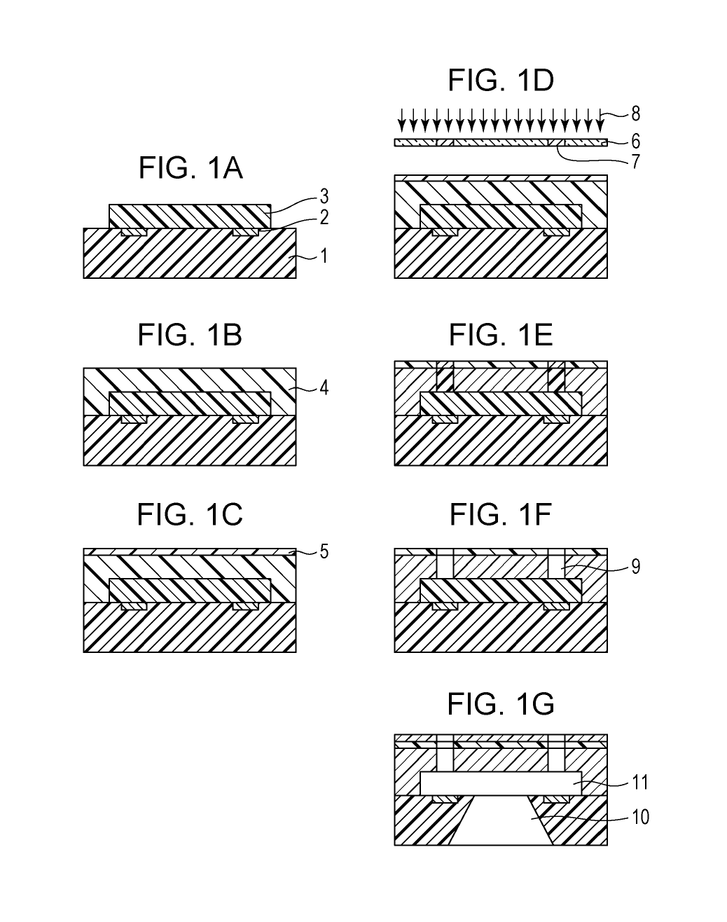

First, as illustrated in FIG. 1A, a silicon substrate 1 is prepared. On the front surface side of the silicon substrate 1, energy generating elements 2 containing TaSiN and the like are formed. Furthermore, a mold material 3 of a flow passage is formed. The mold material 3 is formed with a positive photosensitive resin, for example. The positive photosensitive resin is suitably a photodecomposition type resin and polymethyl isopropenyl ketone, polymethyl methacrylate, polymethyl glutaral imide, and the like are specifically mentioned. In particular, polymethyl isopropenyl ketone is suitable. As a method for forming the mold material 3 containing a positive photosensitive resin, the positive photosensitive resin is dissolved in a solvent as appropriate, and then applied to a substrate or the like by a spin coating method, for example. Then, the solvent is evaporated by baking, and then patterning is performed. As a patterning method, the positive photosensitive resin is irradiated with activation energy rays capable of exposing the same through a mask as necessary, and then subjected to pattern exposure. Then, by performing development using a solvent capable of dissolving the exposed portion or the like, the mold material 3 is formed.

Next, as illustrated in FIG. 1B, a first photosensitive resin layer 4 is formed in such a manner as to cover the mold material 3. Examples of a method for forming the first photosensitive resin layer 4 include a method including dissolving a formation material (first photosensitive resin layer) of the first photosensitive resin layer 4 in a solvent as appropriate, and then applying the solution onto the substrate 1 and the mold material 3 by a spin coating method, for example. When using the solvent, it is suitable to select and use a solvent which is hard to dissolve the mold material 3.

Next, a second photosensitive resin layer 5 is formed on the first photosensitive resin layer 4 as illustrated in FIG. 1C. By this process, the first photosensitive resin layer 4 and the second photosensitive resin layer 5 are formed. In this example, the second photosensitive resin layer 5 is a water-repellent layer. The second photosensitive resin layer 5 is formed by dissolving a formation material (second photosensitive resin) of the second photosensitive resin layer 5 in a solvent as appropriate, and then applying this solution onto the first photosensitive resin layer 4 by a spin coating method or a slit coating method, for example.

Next, as illustrated in FIG. 1D, the first photosensitive resin layer 4 and the second photosensitive resin layer 5 are simultaneously exposed. The exposure is performed by irradiating the layers with ultraviolet rays 8 using a mask 6 having light shielding regions 7, for example. As the ultraviolet rays 8, i-rays having a wavelength of 365 nm are used. In FIG. 1D, the first photosensitive resin layer 4 and the second photosensitive resin layer 5 show an example of the negative photosensitive resin.

Next, as illustrated in FIG. 1E, the first photosensitive resin layer 4 and the second photosensitive resin layer 5 are simultaneously heated. By heating, the curing reaction of the first photosensitive resin layer 4 and the second photosensitive resin layer 5 is accelerated, the reaction of the exposed portion rapidly progresses, and the resistance increases in a development process later. In this process, an ether bond generates by the reaction of an epoxy group depending on the case between the first photosensitive resin layer 4 and the second photosensitive resin layer 5. Moreover, between the first photosensitive resin layer 4 and the second photosensitive resin layer 5, a dehydration condensation reaction of a hydroxyl group and a silanol group also progresses in some cases. As a result, a strong bond is formed between the first photosensitive resin layer 4 and the second photosensitive resin layer 5, and the adhesiveness increases.

Furthermore, as illustrated in FIG. 1F, the first photosensitive resin layer 4 and the second photosensitive resin layer 5 are simultaneously developed. Thus, ejection ports 9 are formed, and the first photosensitive resin layer 4 and the second photosensitive resin layer 5 are simultaneously patterned. A developing solution may be any liquid insofar as the first photosensitive resin layer 4 and the second photosensitive resin layer 5 can be developed and, for example, methyl isobutyl ketone, xylene, a mixed liquid thereof, and the like are used. After the development, rinse treatment is performed with isopropanol and the like.

Next, as illustrated in FIG. 1G, the silicon substrate 1 is etched by TMAH or the like to form a supply port 10. Furthermore, the mold material 3 is removed with ethyl acetoacetate or the like to form a liquid flow passage 11.

Finally, electrical connection for driving the energy generating elements 2 and connection of a supply member for supplying liquid and the like are performed, whereby a liquid ejection head is produced.

FIG. 2A is a view in which the liquid ejection head is viewed from the position facing the surface to which the ejection port 9 is opened. As illustrated in FIG. 2A, the ejection port 9 is opened in the second photosensitive resin layer 5. FIG. 2B is a view in which a side surface portion of the ejection port 9 of the liquid ejection head is viewed in the same cross section as that of FIG. 1. In the present invention, with respect to the first photosensitive resin layer 4 containing the first resin and the second photosensitive resin layer 5 containing the second resin, the solubility in the solvent contained in the second photosensitive resin of the second resin is higher than the solubility of the first resin. As a result, the second photosensitive resin layer 5 becomes difficult to be compatible with the first photosensitive resin layer 4. Therefore, as illustrated in FIG. 2B, the boundary 12 between the first photosensitive resin layer 4 which is a lower layer and the second photosensitive resin layer 5 which is an upper layer becomes flat, and good patterning can be performed by simultaneous exposure and development. However, when these layers are compatible with each other, a level difference is formed at the boundary 12 between the first photosensitive resin layer 4 which is the lower layer and the second photosensitive resin layer 5 which is the upper layer as illustrated in FIG. 2C in some cases. Or, a projection is formed at the boundary 12 between the first photosensitive resin layer 4 which is the lower layer and the second photosensitive resin layer 5 which is the upper layer as illustrated in FIG. 2D in some cases.

In the present invention, it is suitable to set the sensitivity of the first photosensitive resin layer 4 and the sensitivity of the second photosensitive resin layer 5 to be close to each other. Due to the sensitivities are close to each other, the patterning positions of the first photosensitive resin layer 4 and the second photosensitive resin layer 5 can be arranged by simultaneous exposure and development. When the first photosensitive resin layer 4 and the second photosensitive resin layer 5 are compatible with each other, even in the case where the sensitivities are made close to each other, a possibility is high that the optimal configuration (appropriate type, content, and the like of photoacid generating agent) for each layer is not obtained in the compatible portion, and a level difference or a recess is formed at the boundary portion in some cases. Therefore, in the present invention, the solubility in the solvent contained in the second photosensitive resin layer of the second resin contained in the second photosensitive resin layer is made higher than the solubility of the first resin contained in the first photosensitive resin layer to suppress the compatibility of both the layers.

### Exemplary Embodiments

### Exemplary Embodiment 1

A silicon substrate 1 was prepared, and then a first photosensitive resin layer was formed on the silicon substrate 1. First, as a first resin, 100 parts by mass of a photopolymerizable resin (Trade name: 157S70, manufactured by Mitsubishi Chemical Corporation) and 3 parts by mass of a photoacid generating agent (Trade name: CPI-410S, manufactured by San-Apro Ltd.) were dissolved in 80 part by mass of propylene glycol monoethylether acetate (hereinafter referred to as PGMEA) as a solvent to obtain a coating liquid. The coating liquid was applied onto the silicon substrate 1 by spin coating in such a manner that the film thickness was 10 μm, and then heat-treated at 90° C. for 5 minutes to form a first photosensitive resin layer.

Next, a condensate containing a hydrolytic silane compound was prepared. First, 12.53 g (0.045 mol) of γ-glycidoxypropyl triethoxy silane, 8.02 g (0.0225 mol) of methyl triethoxy silane, 4.46 g (0.0225 mol) of phenyl trimethoxy silane, 0.96 g (0.726 mmol) of a compound represented by the following formula (15), 5.93 g of water, 15.15 g of ethanol, 3.83 g of hydrofluoroether (Trade name: HFE7200, manufactured by Sumitomo 3M) were stirred in a flask having a condenser pipe for 5 minutes at room temperature. Then, by heating and refluxing the mixture for 24 hours, a condensate was prepared.

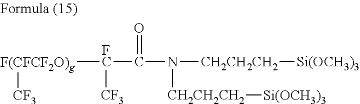

The compound represented by Formula (15) is a mixture and g is an integer of 3 to 10.

1 part by mass of the condensate thus prepared, 5.9 parts by mass of a second resin, and 0.1 part by mass of a photoacid generating agent were diluted with a solvent to prepare 100 parts by mass of a coating liquid. As the second resin, a photopolymerizable resin (Trade name: EHPE-3150, manufactured by Daicel Corporation) was used. As the photoacid generating agent, CPI-410S (Trade name, manufactured by San-Apro Ltd.) was used. As the solvent, one which was prepared in such a manner that the ratio of ethanol:2-butanol:PGMEA was 17:3:1 in terms of mass ratio was used. The coating liquid was applied onto the first photosensitive resin layer using a slit coater, and then heat-treated at 90° C. Thus, the second photosensitive resin layer was formed on the first photosensitive resin layer. The film thickness of the second photosensitive resin layer was 0.5 μm after heating.

The first photosensitive resin layer and the second photosensitive resin layer which were formed was subjected to simultaneous exposure, heating, and development using a mask. The exposure was performed using i-rays and the light shielding region of the mask was set to a circular shape having a diameter of 20 μm. The heating was carried out at 90° C. for 4 minutes. The development was performed with a mixed liquid of MIBK and xylene, and further rinse treatment was performed with isopropanol. Finally, the first photosensitive resin layer and the second photosensitive resin layer were heated at 200° C. for 1 hour for curing. Thus, a cylindrical pattern was formed which had a diameter of the bottom face of 20 μm and which penetrated the first photosensitive resin layer and the second photosensitive resin layer.

### Exemplary Embodiment 2

A pattern was formed in the same manner as in Exemplary Embodiment 1, except using EP4000S (Trade name, manufactured by ADEKA) as the second resin and setting the content of the photoacid generating agent to 0.2 part by mass for the second photosensitive resin layer.

### Exemplary Embodiment 3

A pattern was formed in the same manner as in Exemplary Embodiment 1, except using EX-321L (Trade name, manufactured by Nagase Chemtex Corporation) as the second resin and setting the content of the photoacid generating agent to 0.2 part by mass for the second photosensitive resin layer.

### Exemplary Embodiment 4

A pattern was formed in the same manner as in Exemplary Embodiment 1, except using SP172 (Trade name, manufactured by ADEKA) as the photoacid generating agent and setting the content of the photoacid generating agent to 0.2 part by mass for the second photosensitive resin layer.

### Exemplary Embodiments 5 to 9

Patterns were formed in the same manner as in Exemplary Embodiment 1, except setting the content of a condensate containing each hydrolytic silane compound, the second resin, and the photoacid generating agent to the values shown in Table for the second photosensitive resin layer.

### Exemplary Embodiment 10

As the first resin contained in the first photosensitive resin layer, VG3101 (Trade name, manufactured by Printec Co.) was used. A pattern was formed in the same manner as in Exemplary Embodiment 1 except the change above.

### Exemplary Embodiment 11

As the first resin contained in the first photosensitive resin layer, N865 (Trade name, manufactured by Dainippon Ink & Chemicals) was used. A pattern was formed in the same manner as in Exemplary Embodiment 1 except the change above.

### Comparative Exemplary Embodiment 1

As the first resin contained in the first photosensitive resin layer, EHPE-3150 (Trade name, manufactured by Daicel Corporation) was used. A pattern was formed in the same manner as in Exemplary Embodiment 1 except the change above.

### Comparative Exemplary Embodiment 2

The first resin contained in the first photosensitive resin layer and the second resin contained in the second photosensitive resin layer were replaced. A pattern was formed in the same manner as in Exemplary Embodiment 1 except the change above.

### Evaluation

Cutting was performed at the position where the cylindrical pattern was formed, and the shape of the cross section was observed using a scanning electron microscope (Trade name; S-4300, manufactured by Hitachi High-Technologies). The results were evaluated in accordance with the following criteria.
A: One in which the boundary 12 between the first photosensitive resin layer 4 and the second photosensitive resin layer 5 form a straight line as illustrated in FIG. 2B and good patterning was performed.
B: One in which a step-like shape was formed as illustrated in FIG. 2C or a projection was formed as illustrated in FIG. 2D.

The results are shown in Table.

TABLE

| | | | Example | Example | Example | Example | Example | Example | Example |
|---|---|---|---|---|---|---|---|---|---|
| | | | 1 | 2 | 3 | 4 | 5 | 6 | 7 |
| First | First resin | Type | 157S70 | 157S70 | 157S70 | 157S70 | 157S70 | 157S70 | 157S70 |
| photosensitive | | Part(s) by | 100 | 100 | 100 | 100 | 100 | 100 | 100 |
| resin layer | | mass | | | | | | | |
| | Photopolymerization | Type | CPI- | CPI- | CPI- | CPI- | CPI- | CPI- | CPI- |
| | initiator | | 410S | 410S | 410S | 410S | 410S | 410S | 410S |
| | | Part(s) by | 3 | 3 | 3 | 3 | 3 | 3 | 3 |
| | | mass | | | | | | | |
| | Solvent | Type | PGMEA | PGMEA | PGMEA | PGMEA | PGMEA | PGMEA | PGMEA |
| | | Part(s) by | 80 | 80 | 80 | 80 | 80 | 80 | 80 |
| | | mass | | | | | | | |
| Second | Second resin | Type | EHPE | EP4000S | EX-321L | EHPE | EHPE | EHPE | EHPE |
| photosensitive | | Part(s) by | 5.90 | 5.90 | 5.90 | 5.90 | 5.90 | 5.90 | 5.90 |
| resin layer | | mass | | | | | | | |
| | Photopolymerization | Type | CPI- | CPI- | CPI- | SP172 | CPI- | CPI- | CPI- |
| | initiator | | 410S | 410S | 410S | | 410S | 410S | 410S |
| | | Part(s) by | 0.10 | 0.20 | 0.20 | 0.20 | 0.10 | 0.10 | 0.15 |
| | | mass | | | | | | | |
| | Condensate | Condensation | 55% | 55% | 55% | 55% | 55% | 55% | 55% |
| | | Degree | | | | | | | |
| | | Part(s) by | 1.00 | 1.00 | 1.00 | 1.00 | 0.07 | 0.70 | 1.40 |
| | | mass | | | | | | | |
| | Solvent 1 | Type | EtOH | EtOH | EtOH | EtOH | EtOH | EtOH | EtOH |
| | | Part(s) by | 17 | 17 | 17 | 17 | 17 | 17 | 17 |
| | | mass | | | | | | | |
| | Solvent 2 | Type | 2-BuOH | 2-BuOH | 2-BuOH | 2-BuOH | 2-BuOH | 2-BuOH | 2-BuOH |
| | | Part(s) by | 3 | 3 | 3 | 3 | 3 | 3 | 3 |
| | | mass | | | | | | | |
| | Solvent 3 | Type | PGMEA | PGMEA | PGMEA | PGMEA | PGMEA | PGMEA | PGMEA |
| | | Part(s) by | 1 | 1 | 1 | 1 | 1 | 1 | 1 |
| | | mass | | | | | | | |

| | | | | | | | |
|---|---|---|---|---|---|---|---|
| Evaluation | A | A | A | A | A | A | A |

| | | | Example | Example | Example | Example | Comparative | Comparative |
|---|---|---|---|---|---|---|---|---|
| | | | 8 | 9 | 10 | 11 | Example 1 | Example 2 |
| First | First resin | Type | 157S70 | 157S70 | VG3101 | N865 | EHPE | EHPE |
| photosensitive | | Part(s) by | 100 | 100 | 100 | 100 | 100 | 100 |
| resin layer | | mass | | | | | | |
| | Photopolymerization | Type | CPI- | CPI- | CPI- | CPI- | CPI- | CPI- |
| | initiator | | 410S | 410S | 410S | 410S | 410S | 410S |
| | | Part(s) by | 3 | 3 | 3 | 3 | 3 | 3 |
| | | mass | | | | | | |
| | Solvent | Type | PGMEA | PGMEA | PGMEA | PGMEA | PGMEA | PGMEA |
| | | Part(s) by | 80 | 80 | 80 | 80 | 80 | 80 |
| | | mass | | | | | | |
| Second | Second resin | Type | EHPE | EHPE | EHPE | EHPE | EHPE | 157S70 |
| photosensitive | | Part(s) by | 5.90 | 5.90 | 5.90 | 5.90 | 5.90 | 5.90 |
| resin layer | | mass | | | | | | |
| | Photopolymerization | Type | CPI- | CPI- | CPI- | CPI- | CPI- | CPI- |
| | initiator | | 410S | 410S | 410S | 410S | 410S | 410S |
| | | Part(s) by | 0.15 | 0.20 | 0.10 | 0.10 | 0.10 | 0.10 |
| | | mass | | | | | | |
| | Condensate | Condensation | 55% | 55% | 55% | 55% | 55% | 55% |
| | | Degree | | | | | | |
| | | Part(s) by | 2.80 | 3.50 | 1.00 | 1.00 | 1.00 | 1.00 |
| | | mass | | | | | | |
| | Solvent 1 | Type | EtOH | EtOH | EtOH | EtOH | EtOH | EtOH |
| | | Part(s) by | 17 | 17 | 17 | 17 | 17 | 17 |
| | | mass | | | | | | |
| | Solvent 2 | Type | 2-BuOH | 2-BuOH | 2-BuOH | 2-BuOH | 2-BuOH | 2-BuOH |
| | | Part(s) by | 3 | 3 | 3 | 3 | 3 | 3 |
| | | mass | | | | | | |
| | Solvent 3 | Type | PGMEA | PGMEA | PGMEA | PGMEA | PGMEA | PGMEA |
| | | Part(s) by | 1 | 1 | 1 | 1 | 1 | 1 |
| | | mass | | | | | | |

| | | | | | | |
|---|---|---|---|---|---|---|
| Evaluation | A | A | A | A | C | C |

In Exemplary Embodiments 1 to 11, the second resin contained in the second photosensitive resin layer has higher solubility in the solvent contained in the second photosensitive resin layer than the solubility of the first resin contained in the first photosensitive resin layer. As a result, a good pattern shapes is obtained.

On the other hand, in Comparative Exemplary Embodiment 1, the second resin and the first resin are the same and also have the same solubility in the solvent contained in the second photosensitive resin. As a result, a good pattern shape cannot be obtained. In Comparative Exemplary Embodiment 2, the second resin contained in the second photosensitive resin layer has lower solubility in the solvent contained in the second photosensitive resin layer than the solubility in the first resin contained in the first photosensitive resin layer. As a result, a good pattern shape cannot be obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-161635, filed Aug. 7, 2014 which is hereby incorporated by reference herein in its entirety.

What is claimed is:

1. A method for patterning a photosensitive resin layer, the method comprising:
forming, on a first photosensitive resin layer containing a first resin, a second photosensitive resin layer containing a second resin different from the first resin and a solvent; and
patterning the first photosensitive resin layer and the second photosensitive resin layer by simultaneously exposing and developing the first photosensitive resin layer and the second photosensitive resin layer, wherein
the second photosensitive resin layer is a water-repellent layer and the second resin has higher solubility in the solvent than the solubility of the first resin.

2. The method for patterning a photosensitive resin layer according to claim 1, wherein the second photosensitive resin layer contains a photoacid generating agent.

3. The method for patterning a photosensitive resin layer according to claim 1, wherein the first photosensitive resin layer contains a photoacid generating agent.

4. The method for patterning a photosensitive resin layer according to claim 1, wherein the first resin is a photopolymerizable resin having a polyfunctional cationic photopolymerizable group.

5. The method for patterning a photosensitive resin layer according to claim 1, wherein the second resin is a photopolymerizable resin having a polyfunctional cationic photopolymerizable group.

6. The method for patterning a photosensitive resin layer according to claim 1, wherein the second photosensitive resin layer contains a condensate obtained by condensing a hydrolytic silane compound having a perfluoropolyether group and a hydrolytic silane compound having an epoxy group.

7. The method for patterning a photosensitive resin layer according to claim 1, wherein the photoacid generating agent contained in the second photosensitive resin layer is a photoacid generating agent containing a cationic part structure represented by Formula (7) shown below and an anionic part structure represented by the Formula (8) shown below, 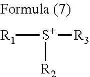
wherein, in Formula (7), R₁ to R₃ each represent an organic group having 1 to 30 carbon atoms which may have a substituent and at least two or more oxygen atoms are contained in all constituent atoms of R₁ to R₃ and, in Formula (8), R₄ represents a hydrocarbon group having 1 to 30 carbon atoms which may be replaced with a fluorine atom, D is selected from a carbon atom, a nitrogen atom, a phosphorus atom, a boron atom, and an antimony atom, and E is selected from —S(═O)₂—, a fluoride alkyl group, —CF₂—O—, —CF₂—C(═O)—, —CF₂—C(═O)—O—, —CF₂—O—C(═O)—, and a single bond, R₄ represents a hydrocarbon group having 1 to 30 carbon atoms which may be replaced with a fluorine atom, m and n represent integers of m+n=3 and n=0 to 2 when D is a carbon atom or integers of m+n=2 and n=0 or 1 when D is a nitrogen atom, and m and n represent integers of m+n=6 and n=0 to 6 when D is a phosphorus atom or an antimony atom or integers of m+n=4 and n=0 to 3 when D is a boron atom [chemical structure]
